(19) United States
(12) Patent Application Publication
(10) Pub. No.: US 2024/0418755 A1
(43) Pub. Date: Dec. 19, 2024

(54) METHOD FOR ESTABLISHING ELECTRICAL CONSUMPTION OF AN ELECTRICAL INSTALLATION

(71) Applicant: SAGEMCOM ENERGY & TELECOM SAS, Bois-Colombes (FR)

(72) Inventors: Henri TEBOULLE, Bois-Colombes (FR); Lucas LEBAILLY, Bois-Colombes (FR); Clément MAGOT, Bois-Colombes (FR)

(73) Assignee: SAGEMCOM ENERGY & TELECOM SAS, Bois-Colombes (FR)

(21) Appl. No.: 18/733,662

(22) Filed: Jun. 4, 2024

(30) Foreign Application Priority Data
Jun. 14, 2023 (FR) 2306043

(51) Int. Cl. G01R 21/133

(52) U.S. Cl. CPC G01R 21/1331

(57) ABSTRACT

To establish an electrical consumption of an electrical installation that is electrically supplied by at least one phase and is monitored by an electricity meter, a method implemented by a controller of the electricity meter includes: obtaining, for each phase, samples of voltage measurements and samples of current measurements; applying an amplitude adjustment K_{U} and a phase adjustment Δφ to the voltage measurement samples to obtain adjusted voltage samples; applying an amplitude adjustment K_{I} and a phase adjustment Δφ′ to the current measurement samples to obtain adjusted current samples; making at least one power calculation from the adjusted voltage and current samples; and establishing the electrical consumption from said at least one power calculation.

### TECHNICAL FIELD

The present invention relates to an adjustment of measurements by an electricity meter in order to take into account lack of precision in characteristics of components of the electricity meter that are used for making voltage and current measurements serving to establish electrical consumption of an electrical installation monitored by the electricity meter.

### PRIOR ART

In order to establish the electrical consumption of an electrical installation, an electricity meter makes power calculations using samples of alternating voltage and current measurements at the input of the electrical installation. The measurements of alternating voltage and current are made by means of electronic components: the voltage measurements are typically made by means of voltage divider bridges; in single phase, the current measurements are typically made by means of measuring shunts; in multiphase (e.g. three phase), the current measurements are typically made by means of toruses.

FIG. 1 illustrates schematically an arrangement for obtaining samples of alternating voltage and current measurement, between a phase line P and a neutral line N, in a single-phase electricity meter.

A voltage divider bridge is implemented by means of resistors R1 and R2 between the neutral line N and ground. An analogue to digital converter C2 placed at a junction point of the resistors R1 and R2 makes it possible to obtain voltage measurement samples.

A shunt, implemented by a calibrated resistor R3, is placed on the phase line P. The phase line P is here connected to ground. A current measuring chain CMC coupled to an analogue to digital converter C1 makes it possible to obtain current measurement samples.

The electricity meter comprises a controller CTRL configured to establish electrical consumption from power calculations made using the samples of alternating voltage and current measurement obtained, as described below in relation to FIG. 3.

FIG. 2 illustrates schematically an arrangement for obtaining samples of alternating voltage and current measurement, between a phase line P and a neutral line N, in a multi-phase (e.g. three-phase), electricity meter. The neutral line N is here connected to ground.

A voltage divider bridge is implemented by means of resistors R1 and R2 between the phase line P in question and ground. An analogue to digital converter C2 placed at a junction point of the resistors R1 and R2 makes it possible to obtain voltage measurement samples.

A torus T is placed on the phase P, with a resistor R4 in parallel. A current measuring chain CMC coupled to an analogue to digital converter C1 makes it possible to obtain current measurement samples.

The arrangement in FIG. 2 is replicated for each phase, the controller CTRL being however here common to the various phases. The controller CTRL is thus configured to establish electrical consumption from power calculations made using the samples of alternating voltage and current measurement obtained for each of the phases.

The actual characteristics of the shunts, toruses and resistors are specific to each electricity meter. By way of example, the precision of a shunt is given at ±5% and that of the resistors at ±1%, and a torus may shift the current signal out of phase by several degrees. It is then usual to adjust the results of the power calculations to compensate for a difference in effective precision of characteristics of the electronic components used for making the alternating voltage and current measurements.

Thus, as illustrated on FIG. 3, the controller CTRL makes for example an active power calculation P and a reactive power calculation Q, from the samples of voltage measurements U and current measurements I obtained. The phase shift and the gain due to the torus for each phase in multiphase (e.g. three-phase), or to the shunt in single phase, are compensated for by adjusting the powers P and Q by means of a matrix calculation MAT in order to obtain a corrected active power Pm and a corrected reactive power Qm. The matrix calculation MAT includes respectively a predefined phase compensation Δφ and a predefined amplitude compensation K.

Given that the power calculations are complex calculations incorporating a sum that is a multiple of multiplications of voltage and current samples, a phase compensation Δφ″ and an amplitude compensation K in these power calculations gives rise to residual lack of precision. This residual lack of precision is all the greater in multiphase (e.g. three-phase) because the phase shifts in particular related to the toruses are different from one phase to another.

It is therefore desirable to overcome these drawbacks of the prior art.

### DISCLOSURE OF THE INVENTION

A method is proposed here for establishing an electrical consumption of an electrical installation that is electrically supplied by at least one phase and is monitored by an electricity meter, the method being implemented by a controller of the electricity meter and comprising: obtaining, for each phase, samples of voltage measurements and samples of current measurements; applying an amplitude adjustment K_{U} and a phase adjustment Δφ to the voltage measurement samples to obtain adjusted voltage samples; applying an amplitude adjustment K_{I} and a phase adjustment Δφ′ to the current measurement samples to obtain adjusted current samples; making at least one power calculation from the adjusted current samples; and establishing the electrical consumption from said at least one power calculation. In addition, to obtain the adjusted current samples, the method furthermore comprises: applying a supplementary adjustment K′ to the current measurement samples to compensate for a spreading of voltage measurement samples with respect to the current measurement samples.

Thus, by applying the amplitude and phase adjustment to the measurement samples rather than to said at least one power calculation, better metrology precision is obtained. In addition, spreading of voltage measurement samples with respect to the current measurement samples is compensated for, which increases the precision.

According to a particular embodiment, the phase adjustment Δφ is applied by interpolation, where, between two successive voltage measurement samples Uₙ₋₁ and Uₙ at respective instants tₙ₋₁=(n−1)×T_{E} and tₙ=n×T_{E} in accordance with a sampling period T_{E}, the interpolation supplies a sample Uₙ₋₁₊ᵣ at a fictitious sampling instant tₙ₋₁₊ᵣ=(n−1+r)×T_{E}, with r such that Δφ=2πr, and the phase adjustment Δφ′ is applied by interpolation, where, between two successive current measurement samples Iₙ₋₁ and Iₙ at the respective instants tₙ₋₁=(n−1)×T_{E} and tₙ=n×T_{E}, the interpolation supplies a sample I_{n-1+r′} at a fictitious sampling instant t_{n-1+r′}=(n−1+r′)×T_{E}, with r′ such that Δφ′=2πr′.

According to one particular embodiment, the interpolation is linear, where the linear interpolation provides interpolated voltage samples Uₙ₋₁₊ᵣ and interpolated current samples I_{n-1+r′} such that

$$\begin{matrix}{U}_{n - 1 + r} = ( 1 + {K}_{U} ) \times ( r \times {U}_{n} + ( 1 - r ) \times {U}_{n - 1} ) and \\ {I}_{n - 1 + {r}^{′}} = ( 1 + {K}_{I} ) \times ( {r}^{′} \times {I}_{n} + ( 1 - {r}^{′} ) \times {I}_{n - 1} ) + {K}_{I}^{′} \times {U}_{n - 1 + r}\end{matrix}$$

According to one particular embodiment, the electrical installation that is monitored by the electricity meter is supplied in three phase. Thus the adjustment for amplitude and phase on the measurement samples is even more precise than it would be by adjusting for amplitude and phase on said at least one power calculation (because particularly of distinct phase shifts introduced by toruses used on the phases for making the current measurement).

According to one particular embodiment, said at least one power calculation is an active power and/or reactive power and/or apparent power calculation.

A computer program is also proposed here, comprising program code instructions causing an implementation of the method, when said instructions are executed by a smart-meter processor.

An information storage medium is also proposed here, storing such program code instructions.

An electricity meter controller is also proposed here, which is configured to establish an electrical consumption of an electrical installation that is electrically supplied by at least one phase and is monitored by the electricity meter, said controller comprising electronic circuitry configured for: obtaining, for each phase, samples of voltage measurements and samples of current measurements; applying an amplitude adjustment K_{U} and a phase adjustment Δφ to the voltage measurement samples to obtain adjusted voltage samples; applying an amplitude adjustment K_{I} and a phase adjustment Δφ′ to the current measurement samples to obtain adjusted current samples; making at least one power calculation from the adjusted voltage and current samples; and establishing the electrical consumption from said at least one power calculation. In addition, to obtain the adjusted current samples, the method furthermore comprises: applying a supplementary adjustment K′_{I} to the current measurement samples to compensate for a spreading of voltage measurement samples with respect to the current measurement samples.

An electricity meter equipped with the above controller is also proposed here.

### BRIEF DESCRIPTION OF THE DRAWINGS

The features of the invention mentioned above, as well as others, will emerge more clearly from the reading of the following description of at least one example embodiment, said description being made in relation to the accompanying drawings, among which:

FIG. 1 illustrates schematically an arrangement for obtaining samples of voltage and current measurement in a single-phase electricity meter;

FIG. 2 illustrates schematically an arrangement for obtaining samples of voltage and current measurement per phase in a multi-phase electricity meter;

FIG. 3 illustrates schematically an arrangement for making a power calculation to establish an electrical consumption, according to the prior art;

FIG. 4 illustrates schematically an arrangement for making a power calculation to establish an electrical consumption, according to one embodiment of the present invention;

FIG. 5 illustrates schematically an example of hardware arrangement of a an electricity-meter controller;

FIG. 6 illustrates schematically an algorithm for making a power calculation to establish an electrical consumption, according to one embodiment of the present invention; and

FIG. 7 illustrates schematically an example of linear interpolation used for adjusting samples for phase, according to one embodiment of the present invention.

### DETAILED DISCLOSURE OF EMBODIMENTS

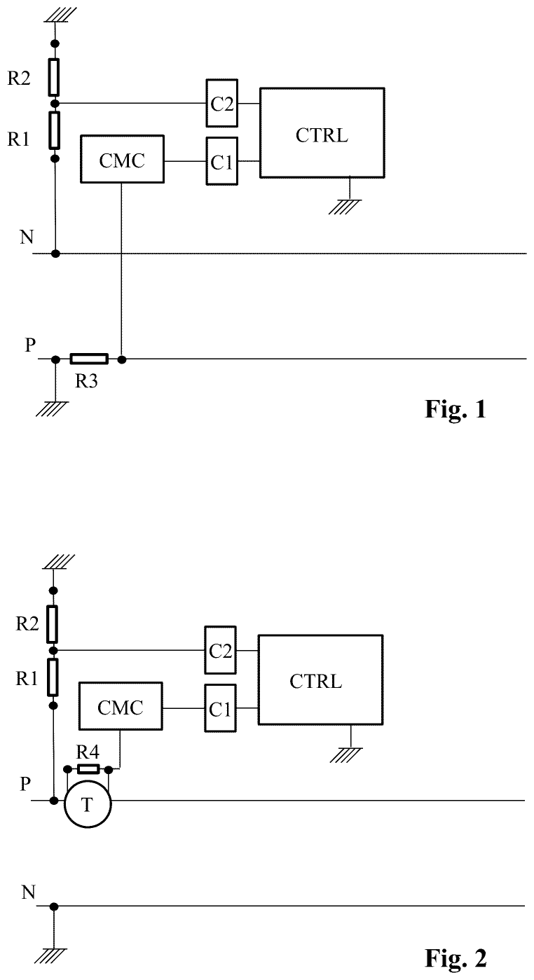

FIG. 4 illustrates schematically an arrangement for making a power calculation to establish an electrical consumption, according to one embodiment of the present invention. The power calculation is made to establish an electrical consumption of an electrical installation that is electrically supplied by at least one phase and is monitored by an electricity meter. FIG. 4 is based on the arrangement in FIG. 1 or the one in FIG. 2 for obtaining samples of voltage and current measurements.

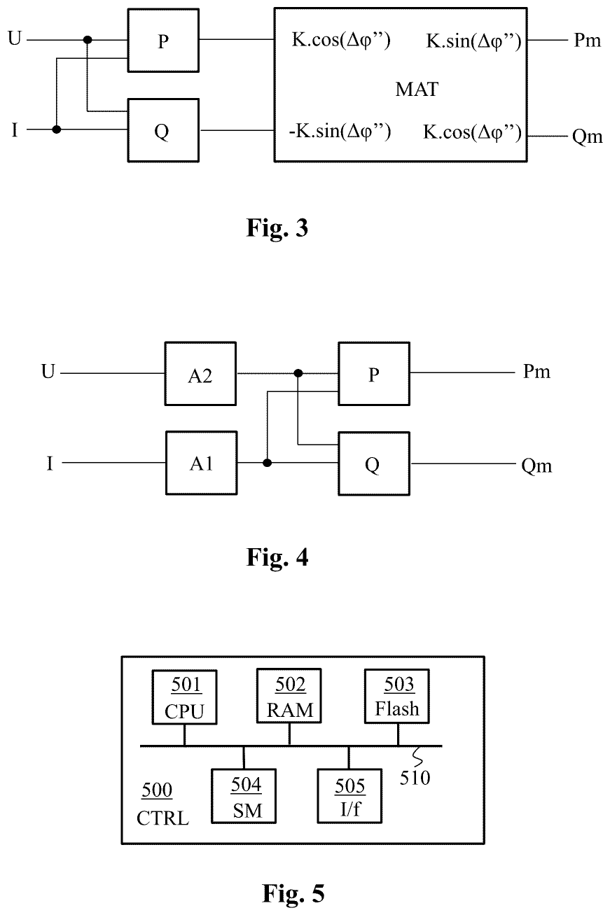

FIG. 4 includes an active power calculation P and a reactive power calculation Q. However, instead of basing these power calculations on the samples of raw voltage U and current I measurements as in the context of FIG. 3, the active power P and reactive power Q calculations use voltage and current samples adjusted in amplitude and phase. Thus the samples of voltage measurements U supplied by the analogue to digital converter C2 undergo an adjustment A2 for amplitude (gain K_{U}) and for phase 40, and the samples of current measurements I supplied by the analogue to digital converter C1 undergo an adjustment A1 for amplitude (gain K_{I}) and for phase Δφ′ (adjustment typically different than for the samples of voltage measurements U).

In obtaining the corrected active power Pm and the corrected reactive power Qm by making the active power P and reactive power Q calculations from voltage and current samples adjusted in amplitude and phase, rather than making an amplitude and phase compensation after the active power P and reactive power Q calculations, the precision of electrical consumption measurement is improved.

FIG. 5 illustrates schematically an example of hardware arrangement of the controller CTRL that is adapted to the power and electrical-consumption calculations according to the present invention.

The controller CTRL 500 comprises, connected by a communication bus 510: a processor or CPU (“central processing unit”) 501; a random access memory (RAM) 502; a read only memory 503, for example of the ROM (“read-only memory”) or EEPROM (“electrically-erasable programmable read-only memory”) type, such as a flash memory; a storage unit SM 504, such as a hard disk drive HDD or an SD (Secure Digital) card reader; and an interface manager I/f 505.

The interface manager I/f 505 enables the controller CTRL 505 to interact with other equipment of the electricity meter, such as for example a transceiver when the electricity meter is a communicating meter. The interface manager I/f 505 enables the controller CTRL 500 to receive the samples of voltage measurements U and I coming from the analogue to digital converters. In a variant embodiment, the analogue to digital converters are included in the controller CTRL 500, for example in the interface manager I/f 505.

The processor 501 is capable of executing instructions loaded in the random access memory 502 from the read-only memory 503, from an external memory, from a storage medium (such as an SD card), or from a communication network. When the controller CTRL 500 is powered up, the processor 501 is capable of reading instructions from the random access memory 502 and executing them. These instructions form a computer program causing the implementation, by the processor 501, of all or some of the steps, methods and operations described here.

All or some of the steps, methods and operations described here can thus be implemented in software form by executing a set of instructions by a programmable machine, for example a processor of the DSP (“digital signal processor”) type, or a microcontroller, or be implemented in hardware form by a machine or a dedicated electronic component (chip) or a dedicated set of electronic components (chipset), for example an FPGA (field-programmable gate array) or an ASIC (application-specific integrated circuit). In general terms, the controller CTRL 500 (and therefore the electricity meter) comprises electronic circuitry adapted and configured to implement the operations, methods and steps described here.

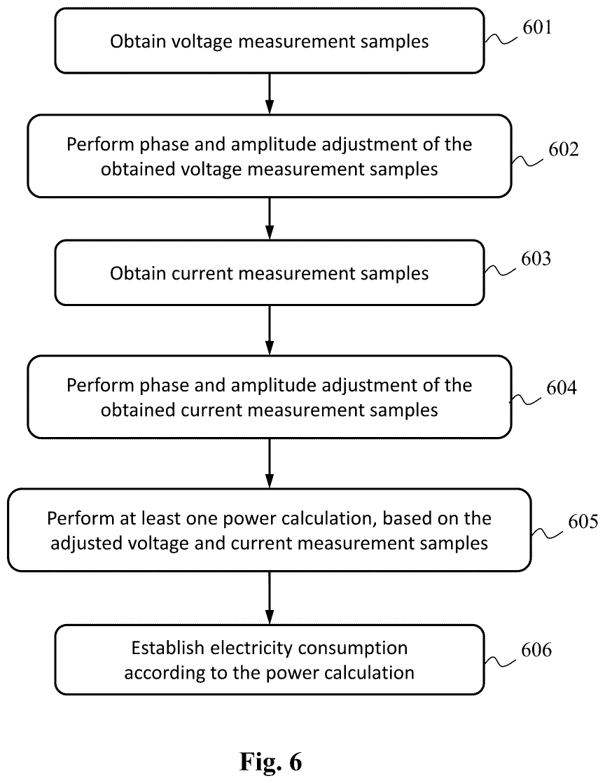

FIG. 6 illustrates schematically an algorithm for making a power calculation to establish an electrical consumption, according to one embodiment of the present invention.

In a step 601, the controller CTRL obtains voltage measurement samples.

In a step 602, the controller CTRL makes an adjustment for phase Δφ and amplitude K_{U} of the voltage measurement samples obtained in order to obtain adjusted voltage samples.

The steps 601 and 602 are performed for each phase (i.e. for each of the three phases in three phase).

In a step 603, the controller CTRL obtains current measurement samples.

In a step 604, the controller CTRL makes an adjustment for phase Δφ′ and amplitude K/of the current measurement samples obtained in order to obtain adjusted current samples.

The steps 603 and 604 are performed for each phase (i.e. for each of the three phases in three phase).

In one particular embodiment, the controller CTRL obtains a voltage sample adjusted for phase Uₙ₋₁₊ᵣ by interpolation between the voltage measurement sample obtained Uₙ₋₁ and the voltage measurement sample obtained Uₙ, defining r such that Δφ=2πr, and then by applying the amplitude adjustment Ky. In a similar manner, the controller CTRL obtains a current sample adjusted for phase Iₙ₋₁₊ᵣ′ by interpolation between the current measurement sample obtained Iₙ₋₁ and the current measurement sample obtained Iₙ, and then by applying the amplitude adjustment K_{I}(defining r′ such that Δφ′=2πr′).

The interpolation can be quadratic, cubic or spline.

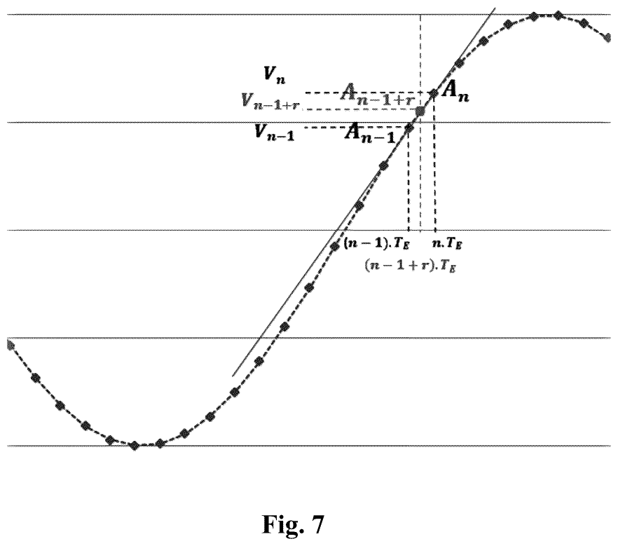

In one particular embodiment, the interpolation is linear, as illustrated schematically on FIG. 7. FIG. 7 comprises points, on a sinusoidal curve, that represent samples of measurements (of voltage or current) as supplied by a said analogue to digital converter. The time is shown on the X axis and the measurement sample values are shown on the Y axis.

The samples correspond to measurements made (supplied by the analogue to digital converters) over a sampling period T_{E}, for example equal to 384.62 μs, therefore corresponding to a sampling frequency f_{E} of 2600 Hz. The points Aₙ₋₁ and Aₙ correspond to successive measurement samples, at respective measurement instants tₙ₋₁=(n−1)×T_{E} and tₙ=n×T_{E}, and have the respective measurement values Vₙ₋₁ and Vₙ. The point Aₙ₋₁₊ᵣ is a point interpolated at a fictional measurement instant tₙ₋₁₊ᵣ=(n−1+r)×T_{E}, with an interpolated amplitude value Vₙ₋₁₊ᵣ. Then: Vₙ₋₁₊ᵣ=r×Vₙ+(1−r)×Vₙ₋₁. Linear interpolation is advantageously simple in terms of calculations and requires few resources. Thus, for each phase:

$$\begin{matrix}{U}_{n - 1 + r} = ( 1 + {K}_{U} ) \times ( r \times {U}_{n} + ( 1 - r ) \times {U}_{n - 1} ) \\ {I}_{n - 1 + {r}^{′}} = ( 1 + {K}_{I} ) \times ( {r}^{′} \times {I}_{n} + ( 1 - {r}^{′} ) \times {I}_{n - 1} )\end{matrix}$$

K_{U}, K_{I}, r and r′ are constants specific to each electricity meter and to each phase. K_{U}, K_{I}, r and r′ are calibrated in the factory using measurements the expected result of which is known and towards which it is necessary to tend. This consists of solving a system of multiple equations with several unknowns.

In addition, the controller CTRL makes a supplementary adjustment to the current measurement samples to compensate for a spreading of voltage measurement samples with respect to the current measurement samples. Such spreading has been found on certain analogue to digital converters that supply the voltage and current samples in the form of multiplexed channels. The controller CTRL then applies a gain K′ to the corresponding (adjusted) voltage sample Uₙ₋₁₊ᵣ for the phase concerned. Then, in the case of the linear interpolation described above, the current samples are adjusted, for each phase, in the following manner:

$${I}_{n - 1 + {r}^{′}} = ( 1 + {K}_{I} ) \times ( {r}^{′} \times {I}_{n} + ( 1 - {r}^{′} ) \times {I}_{n - 1} ) + {K}_{I}^{′} \times {U}_{n - 1 + r}$$

In this case, K_{U}, K_{I}, K′₁, r and r′ are calibrated in the factory using measurements the expected result of which is known and towards which it is necessary to tend. This consists of solving another system of multiple equations with several unknowns.

In a step 605, the controller CTRL makes at least one power calculation using the adjusted voltage and current samples (Uₙ₋₁₊ᵣ and I_{n-1+r′}) for each phase.

The power calculation can be an active power and/or reactive power and/or apparent power calculation.

In the step 606, the controller CTRL establishes an electrical consumption of the electrical installation according to said at least one power calculation of the step 605.

It should be noted that, considering a three-phase electricity meter that comprises three toruses T1, T2 and T3, where the torus T1 is out of phase by Δφ₁ (for example)+1.5°, the torus T2 is out of phase by Δφ₂ (for example)−0.7° and the torus T3 is out of phase by Δφ₃ (for example −1°), it is impossible to select a sampling instant that makes it possible to compensate for these three phase differences simultaneously (since these phase differences are of different values). It is therefore clear that it is preferable to interpolate the samples U and I as proposed in the solution rather than to correct the phase differences by acting on the sampling instant.

1. A method for establishing an electrical consumption of an electrical installation that is electrically supplied by at least one phase and is monitored by an electricity meter, the method being implemented by a controller of the electricity meter and wherein the method comprises:
obtaining, for each phase, samples of voltage measurements and samples of current measurements;
applying an amplitude adjustment K_{U} and a phase adjustment Δφ to the voltage measurement samples to obtain adjusted voltage samples;
applying an amplitude adjustment K_{U} and a phase adjustment Δφ′ to the current measurement samples to obtain adjusted current samples;
making at least one power calculation from the adjusted voltage and current samples; and
establishing the electrical consumption from said at least one power calculation,
wherein the method further comprises, for obtaining the adjusted current samples:
applying a supplementary adjustment to the current measurement samples to compensate for a spreading of voltage measurement samples with respect to the current measurement samples, the supplementary adjustment being an application of gain K′_{I} to said corresponding adjusted voltage samples.

2. The method according to claim 1, wherein the phase adjustment Δφ is applied by interpolation, where, between two successive voltage measurement samples Uₙ₋₁ and Uₙ at respective instants tₙ₋₁=(n−1)×T_{E} and tₙ=n×T_{E} in accordance with a sampling period T_{E}, the interpolation supplies a sample Uₙ₋₁₊ᵣ at a fictitious sampling instant tₙ₋₁₊ᵣ=(n−1+r)×T_{E}, with r such that Δφ=2πr, and
the phase adjustment Δφ′ is applied by interpolation, where, between two successive current measurement samples Iₙ₋₁ and Iₙ at the respective instants tₙ₋₁=(n−1)×T_{E} and tₙ=n×T_{E}, the interpolation supplies a sample I_{n-1+r′} at a fictitious sampling instant tₙ₋₁₊ᵣ′=(n−1+r′)×T_{E}, with r′ such that Δφ′=2πr′.

3. The method according to claim 2, wherein the interpolation is linear, where the linear interpolation provides interpolated voltage samples Uₙ₋₁₊ᵣ and interpolated current samples Iₙ₋₁₊ᵣ such that:
$$\begin{matrix}{U}_{n - 1 + r} = ( 1 + {K}_{U} ) \times ( r \times {U}_{n} + ( 1 - r ) \times {U}_{n - 1} ) and \\ {I}_{n - 1 + {r}^{′}} = ( 1 + {K}_{I} ) \times ( {r}^{′} \times {I}_{n} + ( 1 - {r}^{′} ) \times {I}_{n - 1} ) + {K}_{I}^{′} \times {U}_{n - 1 + r}\end{matrix} .$$

4. The method according to claim 1, wherein the electrical installation that is monitored by the electricity meter is supplied in three phase.

5. The method according to claim 1, wherein said at least one power calculation is an active power and/or reactive power and/or apparent power calculation.

6. A non-transitory storage medium storing program code instructions causing an implementation of the method according to claim 1, when said instructions are read and executed by a processor of an electricity-meter controller.

7. An electricity-meter controller that is configured to establish an electrical consumption of an electrical installation that is electrically supplied by at least one phase and is monitored by the electricity meter, wherein said controller comprises electronic circuitry configured for:
obtaining, for each phase, samples of voltage measurements and samples of current measurements;
applying an amplitude adjustment K_{U} and a phase adjustment Δφ to the voltage measurement samples to obtain adjusted voltage samples;
applying an amplitude adjustment K_{I} and a phase adjustment Δφ′ to the current measurement samples to obtain adjusted current samples;
making at least one power calculation from the adjusted voltage and current samples; and
establishing the electrical consumption from said at least one power calculation, wherein the electronic circuitry is further configured, for obtaining the adjusted current samples, for:
applying a supplementary adjustment to the current measurement samples to compensate for a spreading of voltage measurement samples with respect to the current measurement samples, the supplementary adjustment being an application of gain K′_{I} to said corresponding adjusted voltage samples.

8. An electricity meter comprising a controller according to claim 7.
